(19) United States
(12) Patent Application Publication
(10) Pub. No.: US 2025/0366260 A1
(43) Pub. Date: Nov. 27, 2025

(54) SEMI-CONTINUOUS MULTIPLE QUANTUM WELL PIXEL DESIGN

(71) Applicant: Microsoft Technology Licensing, LLC, Redmond, WA (US)

(72) Inventors: Xuzhou LI, San Jose, CA (US); Ruipeng SUN, Pleasanton, CA (US); William Chao-Hui HWANG, Bellevue, WA (US)

(21) Appl. No.: 18/674,520

(22) Filed: May 24, 2024

(51) Int. Cl. H01L 33/06; H01L 27/15; H01L 33/00; H01L 33/30

(52) U.S. Cl. CPC H10H 20/812; H10H 20/01; H10H 20/824; H10H 29/14

(57) ABSTRACT

A semi-continuous quantum well micro-LED array unit is disclosed. This unit includes a first block of LED pixels comprising a first LED pixel and a second LED pixel. The first and second LED pixels share a first common active region. The unit also includes a second block of LED pixels comprising a third LED pixel and a fourth LED pixel. These LED pixels share a second common active region that is isolated from the first common active region, such that the second common active region is continuously shared by the third and fourth LED pixels. The first block of LED pixels is located proximately to the second block of LED pixels. As a result of the second common active region being isolated from the first common active region, the first block of LED pixels is discrete relative to the second block of LED pixels.

### BACKGROUND

Head mounted devices (HMD), or other wearable devices, are becoming highly popular. These types of devices are able to provide a so-called “extended reality” experience.

The phrase “extended reality” (XR) is an umbrella term that collectively describes various different types of immersive platforms. Such immersive platforms include virtual reality (VR) platforms, mixed reality (MR) platforms, and augmented reality (AR) platforms. The XR system provides a “scene” to a user. As used herein, the term “scene” generally refers to any simulated environment (e.g., three-dimensional (3D) or two-dimensional (2D)) that is displayed by an XR system.

For reference, conventional VR systems create completely immersive experiences by restricting their users' views to only virtual environments. This is often achieved through the use of an HMD that completely blocks any view of the real world. Conventional AR systems create an augmented-reality experience by visually presenting virtual objects that are placed in the real world. Conventional MR systems also create an augmented-reality experience by visually presenting virtual objects that are placed in the real world, and those virtual objects are typically able to be interacted with by the user. Furthermore, virtual objects in the context of MR systems can also interact with real world objects. AR and MR platforms can also be implemented using an HMD. XR systems can also be implemented using laptops, handheld devices, and other computing systems.

Typically, XR systems are implemented as battery-powered devices. One of the primary consumers of battery power is the XR system's display device. In many scenarios, the XR system's display device includes an array of micro light emitting devices (LEDs). There is an ongoing need to try to make these micro-LEDs more efficient and less power consuming.

The subject matter claimed herein is not limited to embodiments that solve any disadvantages or that operate only in environments such as those described above. Rather, this background is only provided to illustrate one exemplary technology area where some embodiments described herein may be practiced.

### BRIEF SUMMARY

In some aspects, the techniques described herein relate to a semi-continuous quantum well micro light emitting diode (LED) array unit including: a first block of LED pixels including a first LED pixel and a second LED pixel, wherein the first LED pixel and the second LED pixel share a first common active region, such that the first common active region is continuously shared by the first LED pixel and the second LED pixel; and a second block of LED pixels including a third LED pixel and a fourth LED pixel, wherein the third LED pixel and the fourth LED pixel share a second common active region that is isolated from the first common active region, such that the second common active region is continuously shared by the third LED pixel and the fourth LED pixel, wherein: the first block of LED pixels is located proximately to the second block of LED pixels in the semi-continuous quantum well micro-LED array unit, and as a result of the second common active region being isolated from the first common active region, the first block of LED pixels is discrete relative to the second block of LED pixels.

In some aspects, the techniques described herein relate to a semi-continuous quantum well micro light emitting diode (LED) array unit including: a first block of LED pixels including a first LED pixel, a second LED pixel, and a third LED pixel, wherein the first LED pixel, the second LED pixel, and the third LED pixel share a first common active region, such that the first common active region is continuously shared by the first LED pixel, the second LED pixel, and the third LED pixel; and a second block of LED pixels including a fourth LED pixel and a fifth LED pixel, wherein the fourth LED pixel and the fifth LED pixel share a second common active region that is isolated from the first common active region, such that the second common active region is continuously shared by the fourth LED pixel and the fifth LED pixel, wherein: the first block of LED pixels is located proximately to the second block of LED pixels in the semi-continuous quantum well micro-LED array unit, and as a result of the second common active region being isolated from the first common active region, the first block of LED pixels is discrete relative to the second block of LED pixels.

In some aspects, the techniques described herein relate to a method for fabricating a semi-continuous quantum well micro light emitting diode (LED) array unit, said method including: using a deep etching mask to discretely isolate a first quantum well of a first block of LED pixels from a second quantum well of a second block of LED pixels, wherein the first block of LED pixels includes a first LED pixel and a second LED pixel, wherein the second block of LED pixels includes a third LED pixel and a fourth LED pixel, and wherein, as a result of using the deep etching mask, the first block of LED pixels is discrete relative to the second block of LED pixels; using a shallow etching mask to partially isolate the first LED pixel from the second LED pixel within the first block of LED pixels, wherein partially isolating the first LED pixel from the second LED pixel involves etching a first portion of the first block of LED pixels to a first depth that causes the first quantum well to continuously span both the first LED pixel and the second LED pixel such that the first quantum well is a first shared quantum well that is shared between the first LED pixel and the second LED pixel; and using the shallow etching mask to partially isolate the third LED pixel from the fourth LED pixel within the second block of LED pixels, wherein partially isolating the third LED pixel from the fourth LED pixel involves etching a second portion of the second block to a second depth that causes the second quantum well to continuously span both the third LED pixel and the fourth LED pixel such that the second quantum well is a second shared quantum well that is shared between the third LED pixel and the fourth LED pixel.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 illustrates an example fabrication process for a micro-LED.

FIG. 2 illustrates components of a semi-continuous quantum well micro-LED.

FIGS. 3A, 3B, and 3C illustrate components of a semi-continuous quantum well micro-LED array unit as well as an abstract fabrication process.

FIG. 4 illustrates differences between various different types of micro-LEDs.

FIG. 5 illustrates different pixels and blocks of pixels in a micro-LED.

FIG. 6 illustrates different matrix arrangements of pixels and blocks.

FIG. 7 illustrates a flowchart of an example method for fabricating a micro-LED.

FIG. 8 illustrates an example computing architecture.

FIG. 9 illustrates an example computer system that can perform any of the disclosed operations.

### DETAILED DESCRIPTION

One of the key challenges of micro-LED technology is the so-called “wall-plug efficiency,” which generally relates to how the optical power emitted versus the electrical power input changes when the pixel pitch becomes smaller (<10 um). Indeed, sometimes more than 90% of the input power is wasted as heat, which significantly impacts the battery life of the display device (e.g., an XR system) and the thermal management of the display device. These inefficiencies arise due to various defects that occur during the fabrication process of the micro-LED.

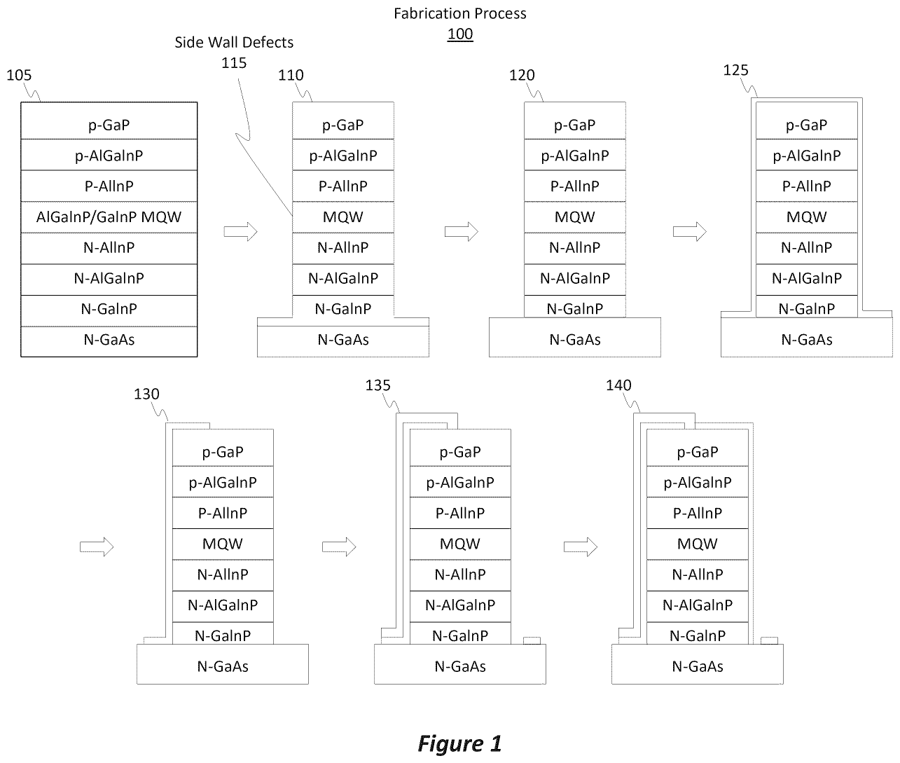

By way of example, FIG. 1 illustrates a technique for fabricating a micro-LED, which can optionally be used in various different display devices, such as a self-emissive display device or any type of micro-display technology (e.g., XR systems). In particular, FIG. 1 shows the fabrication process 100 for the micro-LED.

Initially, the process starts out using a composition of various different materials, as shown by composition 105, which is used to form the micro-LED. Label 110 then illustrates an example etching process (e.g., an inductively coupled plasma reactive ion etching (ICP-RIE) process). During this etching process, it is often the case that various different defects are introduced, particularly in the side wall of the composition, as shown by the side wall defects 115.

Stated differently, conventional micro-LED design involves etching the multiple quantum well (MQW) region. This etching introduces various surface defects (e.g., SRH nonradiative recombination). Passivation does help to marginally compensate for these defects, but the efficiency of the micro-LED efficiency is still degraded.

Continuing with the example, label 120 then illustrates a wet etching process (e.g., an H₃PO₄:HCL wet etching process). Label 125 illustrates a deposition process (e.g., an Al₂O₃ deposition by ALD). Label 130 shows another etching process (e.g., an Al₂O₃ etching by buffered oxide etchant). Label 135 shows another deposition process (e.g., a top and bottom metal deposition by an e-beam evaporator). Label 140 then shows the result of a passivation process in which the composition is treated (e.g., (NH₄)₂Sₓ treatment and Al2O3 deposition).

It should be noted that when micro-LEDs are fabricated (e.g., via a semiconductor fabrication process), the micro-LED performance is typically impacted in a significant manner because the electrical power to optical power efficiency will go down dramatically when the size of the LED is reduced to micro sizes. During the etching portion of the fabrication process, defects will occur, particularly around the edge surface due to the chemical nature of the etching process as well as the non-stability of the material at the surface of the composition. Furthermore, when the size of the LED is reduced, the surface to volume ratio becomes larger (because of reduced volume), resulting in potentially an increased amount of defects in the LED. That is, the volume reduces at a higher rate than the surface area. Thus, defects on the outer surface of the smaller sized substrate will now have a more significant impact to the LED's performance. Consequently, the electrical to optical power efficiency reduces. For certain types of displays (e.g., wearable display devices), this reduction is particularly not ideal because the unit will consume more power, will have a bigger thermal load, and will have a shorter battery life.

With respect to FIG. 1, defects at the MQW are particularly acute as compared to defects at the other substrates. For instance, with the micro-LED, a hole originates from the anode and an electron originates from the cathode. The hole and the electron recombine at the MQW, which is also referred to as the “active region” of the micro-LED. This recombination produces light. Because the MQW operates as the active region, defects in this region have a more pronounced effect on the micro-LED's efficiency as compared to defects in other regions. As the size of the LED is reduced, these problems are exacerbated, as described above.

The above description is one of the major reasons why the use of micro-LED technology has not been widely adopted in the wearable display device industry (most especially for red colors). What is needed, therefore, is an improved technique for designing micro-LEDs so that they do not suffer from the performance issues described above.

The disclosed embodiments provide significant benefits, advantages, and practical applications to the structural design of a micro-LED. With this improved design, the embodiments beneficially increase or improve the operational efficiency of the micro-LED. This increased efficiency results in less power consumption and a smaller thermal load.

Beneficially, the disclosed embodiments are directed to an improved type of micro-LED. In particular, the embodiments are directed to a semi-continuous quantum well micro-LED array unit. This unit includes a first block of LED pixels comprising a first LED pixel and a second LED pixel. Beneficially, the first LED pixel and the second LED pixel share a first common active region, such that the first common active region is continuously shared by the first LED pixel and the second LED pixel.

The unit further includes a second block of LED pixels comprising a third LED pixel and a fourth LED pixel. The third LED pixel and the fourth LED pixel share a second common active region that is isolated from the first common active region, such that the second common active region is continuously shared by the third LED pixel and the fourth LED pixel.

Notably, the first block of LED pixels is located proximately to the second block of LED pixels in the semi-continuous quantum well micro-LED array unit. As a result of the second common active region being isolated from the first common active region, the first block of LED pixels is discrete relative to the second block of LED pixels. This unique configuration provides for an overall improvement in efficiency and crosstalk performance (i.e. reduced crosstalk among the various different pixels).

In some scenarios, additional LEDs can be included. For instance, it might be the case that the first block of LED pixels includes a fifth LED that shares the first common active region. Similarly, the second block of LED pixels may include a sixth LED that shares the second common active region. Optionally, a number of LED pixels in the first block may be different than a number of LED pixels in the second block. In other scenarios, the number may be the same.

In some scenarios, the first block of LED pixels comprises a matrix of pixels having N×N dimensions. In other scenarios, the first block of LED pixels comprises a matrix of pixels having N×M dimensions. Optionally, the semi-continuous quantum well micro-LED array unit may include a third block of LED pixels. The third block of LED pixels can have a third common active region that is shared among the LED pixels of the third block and that is isolated from the first common active region and the second common active region.

Because the second common active region is isolated from the first common active region, this isolation operates to reduce crosstalk between the LED pixels of the second block and the LED pixels of the first block. This isolation also allows for the LEDs to be efficient in their performance and battery consumption. Accordingly, these and numerous other benefits will now be described in more detail throughout the remaining portions of this disclosure.

### Improved Structural Design of a Micro-LED

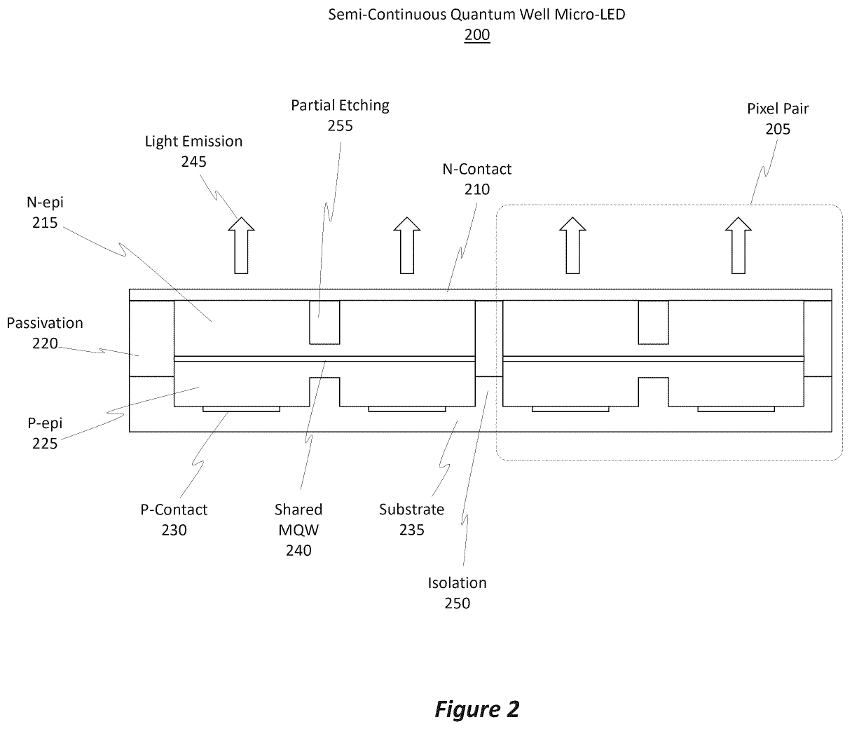

Attention will now be directed to FIG. 2, which illustrates an improved structural design for a micro-LED in the form of a semi-continuous quantum well micro-LED 200. Beneficially, this enhanced structural design improves the surface to volume ratio by configuring the LED pixel to have fewer cuts and less edge surfaces. FIG. 2 shows a 2×2 pixel arrangement. It should be appreciated how this arrangement is but one example of an arrangement and other configurations can also be employed. For example, the arrangement can be an “n×n” arrangement or perhaps even an “n×m” arrangement. As will be described in more detail, each pair of LED pixels shares a common active region (e.g., the MQW region), but each pair is discretely separated from other pairs.

FIG. 2 shows a first pixel pair 205. A second pixel pair is also illustrated but is not labeled as such. The second pixel pair is shown as including an N-contact 210, an N-epi 215, a passivation 220, a P-epi 225, a P-contact 230, a substrate 235, and a shared MQW 240 between the two pixels in the pair. Light is emitted from each pixel, as shown by the arrows, one of which is labeled as light emission 245. Notice, an isolation 250 gap exists between the two pairs of pixels, resulting in those two pairs not sharing a common MQW.

This structural design results in less etching or less cuts being imposed on the LED unit. Because less etching is performed, fewer defects will occur, particularly in the active region. Because fewer defects will occur, the performance and efficiency of the micro-LED will be improved.

In FIG. 2, the etching process was fully performed on the region labeled as isolation 250 as well as the outermost left region of the figure and the outermost right region of the figure. The etching process was only partially performed in the region labeled as partial etching 255. This partial etching allows the shared MQW 240 to be common between the left pixel and the right pixel in the figure. Thus, in this figure, the etching process followed a general pattern comprising a deep cut, a shallow cut, a deep cut, a shallow cut, and another deep cut.

Different patterns can be used depending on the groupings of the pixels. As one example, suppose three pixels were structured to share a common MQW. In this scenario, the pattern would include the following: deep cut, shallow cut, shallow cut, and deep cut. The use of shallow cuts allows the embodiments to maintain a common MQW among a select number of pixels.

In FIG. 2, the only place were defects can arise (due to the etching process) in the active region is on the very lefthand side of the shared MQW 240 and the very righthand side of the shared MQW 240. The central region of the shared MQW 240 is not revealed during the etching process and thus no defects will occur in that portion of the active region. Thus, in the example shown in FIG. 2, a 50% reduction in the amount of defects can be achieved. If a grouping of three pixels shared a common active region, a 66% reduction in the amount of defects can be achieved. Beneficially, the embodiments reduce the non-radiative recombination that occurs in the MQW.

To achieve the above benefits, the embodiments modify the etching and fabrication process. Previously, a single mask was used during the fabrication process to make the various etches. In accordance with the disclosed principles, a plurality of masks are now used to perform the etching process. For instance, a first mask is used to perform all of the deep cuts, resulting in full isolation between the various different pixels. A second mask is used to perform all of the shallow cuts, resulting in the partial isolation between the different pixels and further resulting in the active region being shared between those pixels. In this scenario, the first mask can be considered as a deep mask, and the second mask can be considered as a shallow mask.

Therefore, as compared to traditional etching fabrication techniques, the disclosed embodiments involve additional steps that are not performed in those traditional techniques. As mentioned, the disclosed embodiments employ the use of multiple different masks (having multiple different cut depths) during the etching process whereas the traditional approach employs a single mask having a uniform cut depth.

To rephrase, the embodiments use a first mask to control certain etching depths to fully isolate multiple quantum wells between different blocks of pixels. The embodiments also employ one or more additional masks to control specific edge depths so as to not break or etch through a multiple quantum well that is to be common across multiple pixels belong to a same block.

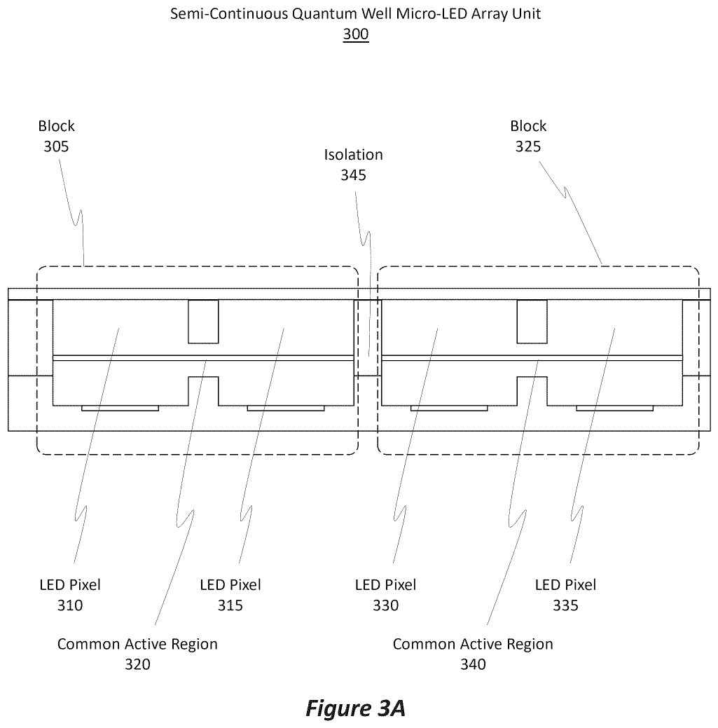

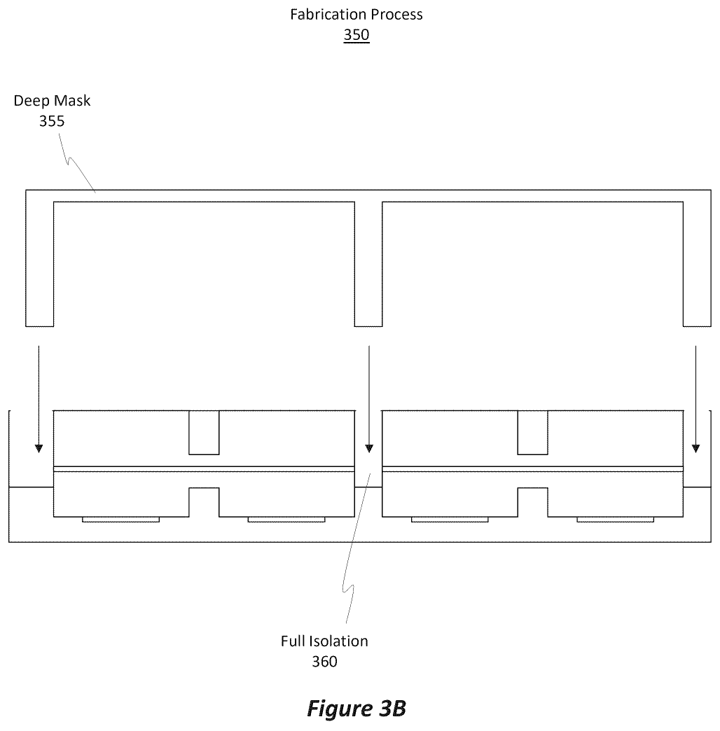

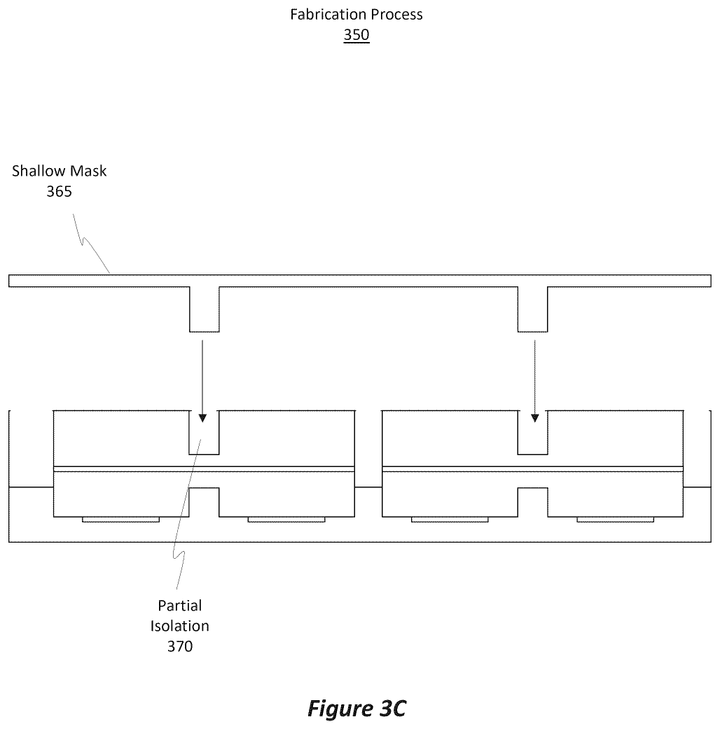

FIGS. 3A, 3B, and 3C provide helpful illustrations regarding the use of multiple different masks. It should be noted how the depictions in these figures do not actually reflect the etching process; rather, they are provided simply for illustrative purposes with respect to the use of different masks. Thus, these depictions should not be viewed as being literal representations of the etching process.

FIG. 3A shows a semi-continuous quantum well micro-LED array unit 300 formed from multiple different blocks of pixels. FIG. 3A shows a first block 305 comprising a first LED pixel 310 and a second LED pixel 315. Notice, the first and second LED pixels 310, 315 share a common active region 320.

FIG. 3A also shows a second block 325 comprising a third LED pixel 330 and a fourth LED pixel 335. Here again, the third and fourth LED pixels 330, 335 share a common active region 340. FIG. 3A also illustrates how the first block 305 is isolated from the second block 325 in that these two blocks do not share a common active region, as evidenced by the separation or isolation 345 between those blocks.

FIG. 3B shows a fabrication process 350 involving the use of a deep mask 355 to generate full isolation 360 between different blocks of pixels. Notice, the use of the deep mask 355 fully severs or cuts through the MQW region (i.e. the active region). As a result, different blocks of pixels are fully isolated from one another in that they do not share a common active region.

FIG. 3C shows the use of a shallow mask 365 to generate partial isolation 370 between individual pixels within a block. Therefore, whereas the deep mask 355 fully separated blocks, the shallow mask 365 partially separated individual pixels. Notice, the use of the shallow mask 365 does not fully sever or cut through the MQW region. Instead, the MQW region is preserved between grouped pixels, thereby allowing that active region to be shared among those grouped pixels. One will appreciate how the different masks are configured to accommodate different groupings of pixels and different blocks of pixels.

Accordingly, these figures (particularly FIG. 3A) illustrate a semi-continuous quantum well micro light emitting diode (LED) array unit. This unit includes a first block of LED pixels comprising a first LED pixel and a second LED pixel. The first LED pixel and the second LED pixel share a first common active region, such that the first common active region is continuously shared by the first LED pixel and the second LED pixel.

The unit further includes a second block of LED pixels comprising a third LED pixel and a fourth LED pixel. The third LED pixel and the fourth LED pixel share a second common active region that is isolated from the first common active region, such that the second common active region is continuously shared by the third LED pixel and the fourth LED pixel.

The first block of LED pixels is located proximately to the second block of LED pixels in the semi-continuous quantum well micro-LED array unit. Also, as a result of the second common active region being isolated from the first common active region, the first block of LED pixels is discrete relative to the second block of LED pixels. Thus, the unit includes some LED pixels that are continuously coupled to one another via a shared active region and some LED pixels that are discrete relative to one another as a result of not sharing a common active region.

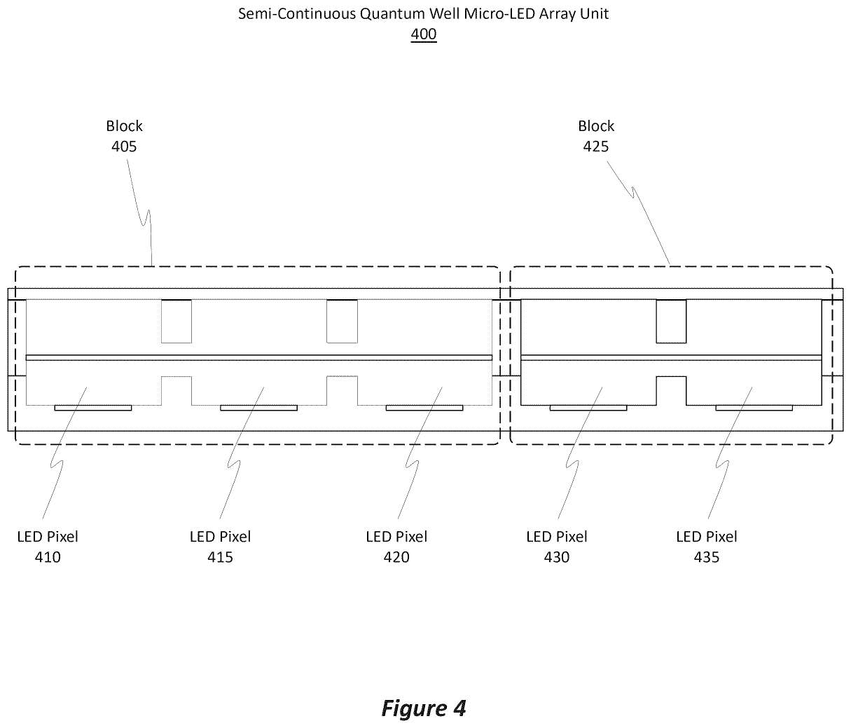

FIG. 4 shows another example implementation of the semi-continuous quantum well micro-LED array unit 400. This unit includes a first block 405. The first block 405 includes three different LED pixels, which include LED pixel 410, LED pixel 415, and LED pixel 420. The unit also includes a second block 425. The second block 425 includes only two LED pixels, which include LED pixel 430 and LED pixel 435. From FIG. 4, one will appreciate how multiple different configurations are possible via the disclosed principles. Some blocks can be configured to have a first number of LED pixels while other blocks can be configured to have a different number of LED pixels. In some scenarios, the size of the pixels can vary, even within a single block. For instance, in one scenario, all pixels within a same block have the same size, or rather the same pixel pitch. In another scenario, one or more pixels in a block have a first size (e.g., a first pixel pitch) and one or more pixels in the same block have a different size (e.g., different pixel pitch). In yet another scenario, a first block of pixels may all have a uniform pixel pitch while a neighboring block of pixels may have pixels of differing pixel pitches. Indeed, different configurations can be used, and a display device can have variable sized pixels. Different masks can be used to configure the different pixel pitches.

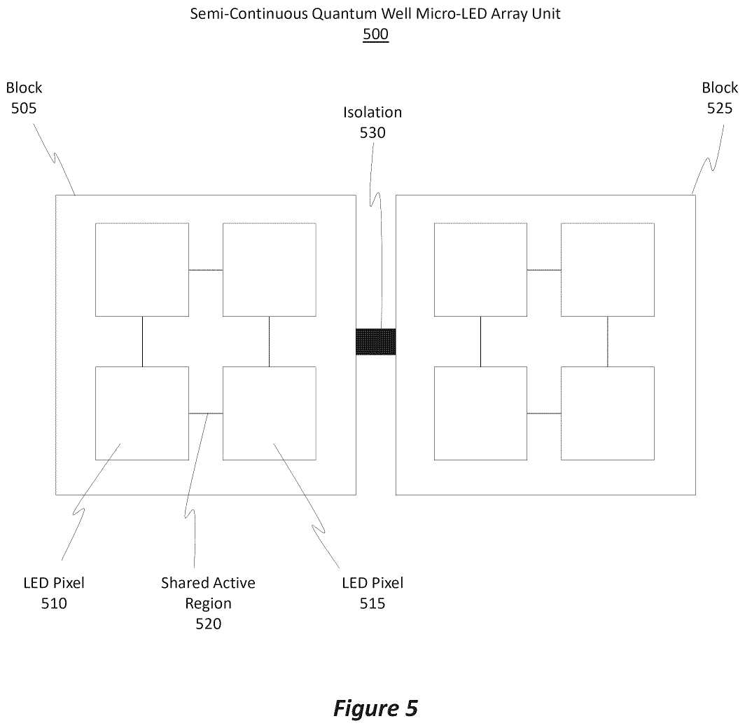

FIG. 5 illustrates another example implementation of a semi-continuous quantum well micro-LED array unit 500. This unit includes a first block 505 having four different LED pixels, two of which are labeled (e.g., LED pixel 510 and LED pixel 515). All of the LED pixels in the first block 505 have a shared active region 520.

FIG. 5 also shows a second block 525 having four different LED pixels. These four pixels also have a shared active region. Notice, isolation 530 exists between the active regions of the first block 505 and the second block 510.

FIG. 5 further shows how different matrices of LED pixels can be included in the unit 500. For instance, the first block 505 has a matrix of LED pixels having N×N dimensions. Other dimensions can also be implemented. For instance, the matrix can be an N×M dimensional matrix.

### Comparison Between Different Structural Configurations

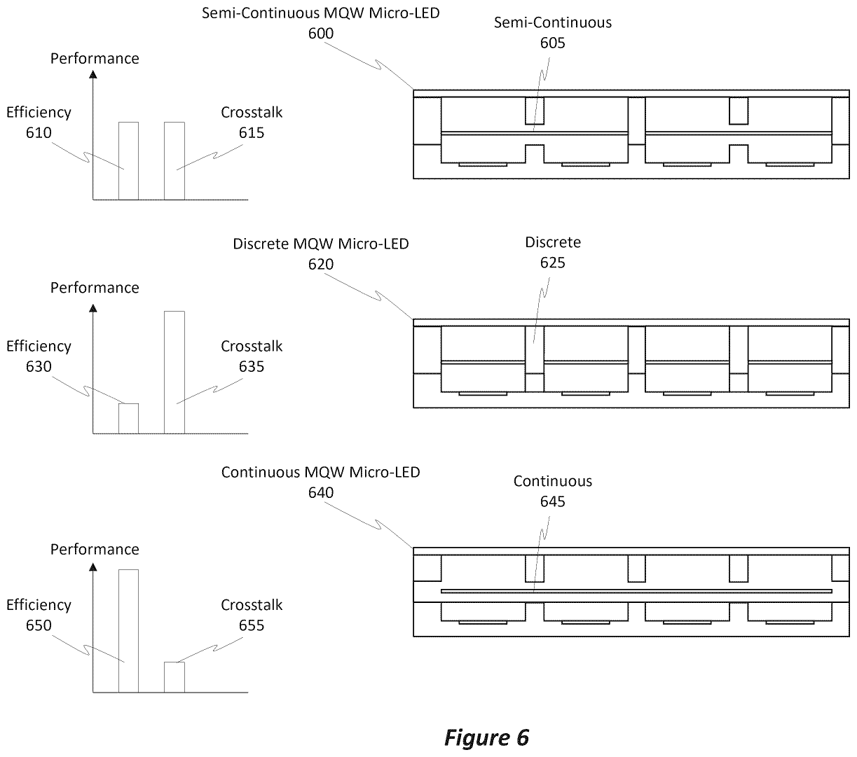

Because of the benefits mentioned previously, one might ask why not just use a fully continuous active region across all pixels. FIG. 6 provides clarification regarding that question.

FIG. 6 shows the disclosed embodiment in the form of the semi-continuous MQW micro-LED 600. Notice, this type of LED has full separation as well as partial separation, as shown by semi-continuous 605.

This improved LED structure provides for “good” efficiency 610. It also provides for “good” crosstalk 615 performance (i.e. reduced crosstalk among the pixels as compared to increased crosstalk). By “good,” it is generally meant that the efficiency is above a threshold level, and the amount of crosstalk is below a threshold level (or the performance of the crosstalk is above a threshold level). A lower amount of crosstalk is desired. Thus, good crosstalk refers to a low amount of crosstalk and good crosstalk “performance” refers to a scenario where the overall amount of crosstalk is reduced. When considered as a whole, the overall characteristics of the semi-continuous MQW micro-LED 600 operate at least at a threshold level of performance.

Now, consider a traditional micro-LED in the form of the discrete MQW micro-LED 620. This type of LED has full separation between each of its pixels, as shown by discrete 625. Notice, the efficiency 630 of this type of pixel is generally poor, but the crosstalk 635 performance is quite high (meaning there is little crosstalk amongst the pixels). When considering the poor efficiency and the high performance crosstalk of the discrete MQW micro-LED 620, the overall performance of the disclosed semi-continuous MQW micro-LED 600 is better.

Now, consider another traditional micro-LED in the form of the continuous MQW micro-LED 640. This type of LED has only partial separation between each of its pixels, as shown by continuous 645. Notice, the efficiency 650 of this type of pixel is quite high, but the crosstalk 655 performance is quite poor (meaning the amount of crosstalk among the pixels is quite high). Poor crosstalk performance plays a significant impact on image quality. That is, crosstalk hampers the quality of the resulting image. When considering the high efficiency but poor crosstalk performance of the continuous MQW micro-LED 640, the overall performance of the disclosed semi-continuous MQW micro-LED 600 is better. Thus, the structural configuration disclosed herein results in an overall better LED, particularly for wearable devices that rely on battery power.

### Example Methods

The following discussion now refers to a number of methods and method acts that may be performed. Although the method acts may be discussed in a certain order or illustrated in a flow chart as occurring in a particular order, no particular ordering is required unless specifically stated, or required because an act is dependent on another act being completed prior to the act being performed.

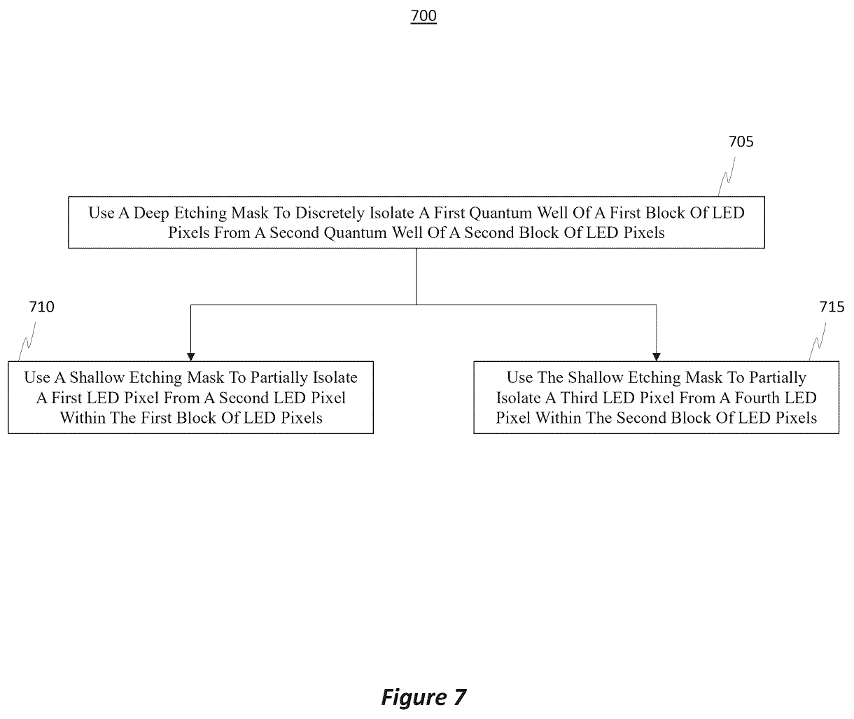

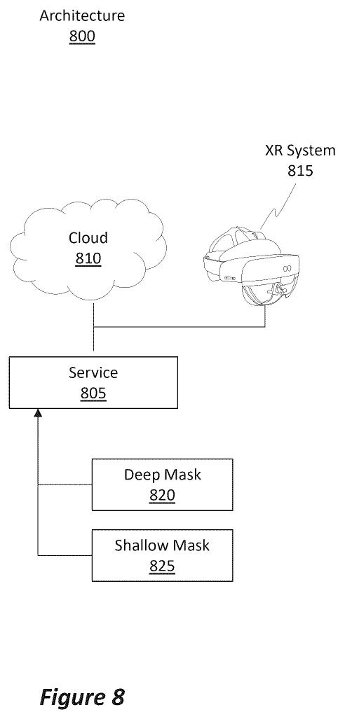

Attention will now be directed to FIG. 7, which illustrates a flowchart of an example method 700 for fabricating a semi-continuous quantum well micro light emitting diode (LED) array unit. Method 700 can be implemented by a service, such as the one shown in FIG. 8. For instance, in FIG. 8, architecture 800 includes a service 805.

As used herein, the term “service” refers to an automated program that is tasked with performing different actions based on input. In some cases, service 805 can be a deterministic service that operates fully given a set of inputs and without a randomization factor. In other cases, service 805 can be or can include a machine learning (ML) or artificial intelligence engine. The ML engine enables the service to operate even when faced with a randomization factor.

As used herein, reference to any type of machine learning or artificial intelligence may include any type of machine learning algorithm or device, convolutional neural network(s), multilayer neural network(s), recursive neural network(s), deep neural network(s), decision tree model(s) (e.g., decision trees, random forests, and gradient boosted trees) linear regression model(s), logistic regression model(s), support vector machine(s) (“SVM”), artificial intelligence device(s), or any other type of intelligent computing system. Any amount of training data may be used (and perhaps later refined) to train the machine learning algorithm to dynamically perform the disclosed operations.

In some implementations, service 805 is a cloud service operating in a cloud 810 environment. In some implementations, service 805 is a local service operating on a local device, such as an XR system 815. In some implementations, service 805 is a hybrid service that includes a cloud component operating in the cloud 810 and a local component operating on a local device. These two components can communicate with one another. Service 805 can help facilitate the fabrication process of a semi-continuous quantum well micro-LED array unit. Service 805 can also facilitate the acts of method 700. Service 805 can be used during the fabrication process to selectively control the use of a deep mask 820 and a shallow mask 825 according to the principles described herein.

Returning to FIG. 7, method 700 shows an act (act 705) of using a deep etching mask to discretely isolate a first quantum well of a first block of LED pixels from a second quantum well of a second block of LED pixels. The first block of LED pixels includes a first LED pixel and a second LED pixel. The second block of LED pixels includes a third LED pixel and a fourth LED pixel. As a result of using the deep etching mask, the first block of LED pixels is discrete relative to the second block of LED pixels.

Act 710 includes using a shallow etching mask to partially isolate the first LED pixel from the second LED pixel within the first block of LED pixels. Partially isolating the first LED pixel from the second LED pixel involves etching a first portion of the first block of LED pixels to a first depth that causes the first quantum well to continuously span both the first LED pixel and the second LED pixel. As a result, the first quantum well is a first shared quantum well that is shared between the first LED pixel and the second LED pixel.

Concurrently or potentially in serial with act 710 is act 715. Act 715 includes using the shallow etching mask to partially isolate the third LED pixel from the fourth LED pixel within the second block of LED pixels. Partially isolating the third LED pixel from the fourth LED pixel involves etching a second portion of the second block to a second depth that causes the second quantum well to continuously span both the third LED pixel and the fourth LED pixel. Consequently, the second quantum well is a second shared quantum well that is shared between the third LED pixel and the fourth LED pixel.

In some cases, the first depth is substantially the same as the second depth. In other cases, the depths can be different. Often, the shallow etching mask is used subsequent in time to the deep etching mask. In some cases, the shallow etching mask can be used prior in time to the use of the deep etching mask. Typically, the shallow etching mask is concurrently used to etch both the first block of LED pixels and the second block of LED pixels. In some cases, however, one of the first or second blocks can be etched first and then the other one of the first or second blocks can be etched second.

Accordingly, the disclosed embodiments are directed to a semi-continuous quantum well micro light emitting diode (LED) array unit. This unit includes a first block of LED pixels comprising a first LED pixel, a second LED pixel, and (optionally) a third LED pixel. The first LED pixel, the second LED pixel, and the third LED pixel share a first common active region, such that the first common active region is continuously shared by the first LED pixel, the second LED pixel, and the third LED pixel.

The unit further includes a second block of LED pixels comprising a fourth LED pixel and a fifth LED pixel. The fourth LED pixel and the fifth LED pixel share a second common active region that is isolated from the first common active region, such that the second common active region is continuously shared by the fourth LED pixel and the fifth LED pixel.

The first block of LED pixels is located proximately to the second block of LED pixels in the semi-continuous quantum well micro-LED array unit. As a result of the second common active region being isolated from the first common active region, the first block of LED pixels is discrete relative to the second block of LED pixels.

Optionally, a number of LED pixels in the first block of LED pixels is the same as a number of LED pixels in the second block of LED pixels. Optionally, a number of LED pixels in the first block of LED pixels is different than a number of LED pixels in the second block of LED pixels.

In some scenarios, prior to an etching process during which the semi-continuous quantum well micro-LED array unit was fabricated, the first common active region was coupled to the second common active region. The etching process broke or removed that coupling.

Optionally, a pixel pitch of the first pixel is less than or equal to 10 micrometers. In some cases, the pixel pitch is less than about 8 micrometers.

Optionally, as a result of (i) the first common active region being common between the LED pixels of the first block, (ii) the second common active region being common between the LED pixels of the second block, and (iii) the first common active region being isolated from the second common active region, a surface area to volume ratio of at least one of the first common active region or the second common active region is a reduced ratio. This reduction is due to a volume of the first or second common active region being increased as compared to a scenario where the active regions are not shared. As another option, a surface area to volume ratio of the first common active region is a reduced ratio due to a volume of the first common active region being increased as compared to a scenario in which the active regions are not shared. As yet another option, a surface area to volume ratio of the first common active region is a reduced ratio due to a surface area of the first common active region being decreased as compared to a scenario where the active regions are not shared.

### Example Computer/Computer Systems

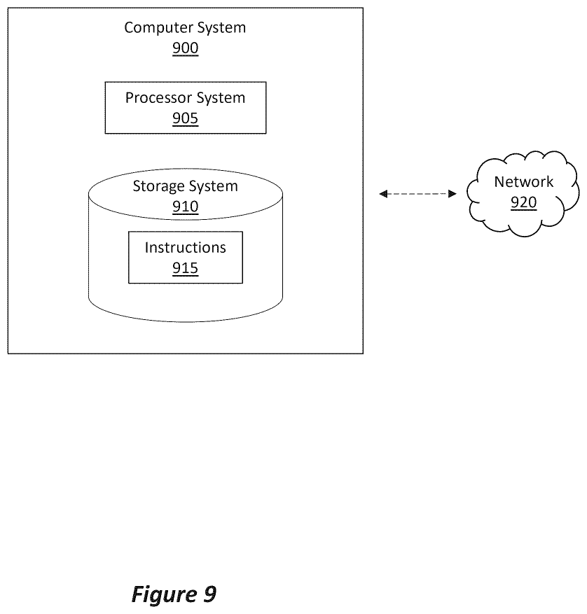

Attention will now be directed to FIG. 9 which illustrates an example computer system 900 that may include and/or be used to perform any of the operations described herein. For instance, computer system 900 can be in the form of the XR system 815 of FIG. 8 and can implement the service 805. Of course, the computer system 900 can take on other forms as well.

For example, computer system 900 may be embodied as a tablet, a desktop, a laptop, a mobile device, or a standalone device, such as those described throughout this disclosure. Computer system 900 may also be a distributed system that includes one or more connected computing components/devices that are in communication with computer system 900. Computer system 900 can help facilitate the fabrication processes mentioned earlier.

In its most basic configuration, computer system 900 includes various different components. FIG. 9 shows that computer system 900 includes a processor system 905 that includes one or more processor(s) (aka a “hardware processing unit”) and a storage system 910.

Regarding the processor(s) of the processor system 905, it will be appreciated that the functionality described herein can be performed, at least in part, by one or more hardware logic components (e.g., the processor(s)). For example, and without limitation, illustrative types of hardware logic components/processors that can be used include Field-Programmable Gate Arrays (“FPGA”), Program-Specific or Application-Specific Integrated Circuits (“ASIC”), Program-Specific Standard Products (“ASSP”), System-On-A-Chip Systems (“SOC”), Complex Programmable Logic Devices (“CPLD”), Central Processing Units (“CPU”), Graphical Processing Units (“GPU”), or any other type of programmable hardware.

As used herein, the terms “executable module,” “executable component,” “component,” “module,” “service,” or “engine” can refer to hardware processing units or to software objects, routines, or methods that may be executed on computer system 900. The different components, modules, engines, and services described herein may be implemented as objects or processors that execute on computer system 900 (e.g. as separate threads).

Storage system 910 may be physical system memory, which may be volatile, non-volatile, or some combination of the two. The term “memory” may also be used herein to refer to non-volatile mass storage such as physical storage media. If computer system 900 is distributed, the processing, memory, and/or storage capability may be distributed as well.

Storage system 910 is shown as including executable instructions 915. The executable instructions 915 represent instructions that are executable by the processor(s) the processor system 905 to perform the disclosed operations, such as those described in the various methods.

The disclosed embodiments may comprise or utilize a special-purpose or general-purpose computer including computer hardware, such as, for example, one or more processors and system memory, as discussed in greater detail below. Embodiments also include physical and other computer-readable media for carrying or storing computer-executable instructions and/or data structures. Such computer-readable media can be any available media that can be accessed by a general-purpose or special-purpose computer system. Computer-readable media that store computer-executable instructions in the form of data are “physical computer storage media” or a “hardware storage device.” Furthermore, computer-readable storage media, which includes physical computer storage media and hardware storage devices, exclude signals, carrier waves, and propagating signals. On the other hand, computer-readable media that carry computer-executable instructions are “transmission media” and include signals, carrier waves, and propagating signals. Thus, by way of example and not limitation, the current embodiments can comprise at least two distinctly different kinds of computer-readable media: computer storage media and transmission media.

Computer storage media (aka “hardware storage device”) are computer-readable hardware storage devices, such as RAM, ROM, EEPROM, CD-ROM, solid state drives (“SSD”) that are based on RAM, Flash memory, phase-change memory (“PCM”), or other types of memory, or other optical disk storage, magnetic disk storage or other magnetic storage devices, or any other medium that can be used to store desired program code means in the form of computer-executable instructions, data, or data structures and that can be accessed by a general-purpose or special-purpose computer.

Computer system 900 may also be connected (via a wired or wireless connection) to external sensors (e.g., one or more remote cameras) or devices via a network 920. For example, computer system 900 can communicate with any number devices or cloud services to obtain or process data. In some cases, network 920 may itself be a cloud network. Furthermore, computer system 900 may also be connected through one or more wired or wireless networks to remote/separate computer systems(s) that are configured to perform any of the processing described with regard to computer system 900.

A “network,” like network 920, is defined as one or more data links and/or data switches that enable the transport of electronic data between computer systems, modules, and/or other electronic devices. When information is transferred, or provided, over a network (either hardwired, wireless, or a combination of hardwired and wireless) to a computer, the computer properly views the connection as a transmission medium. Computer system 900 will include one or more communication channels that are used to communicate with the network 920. Transmissions media include a network that can be used to carry data or desired program code means in the form of computer-executable instructions or in the form of data structures. Further, these computer-executable instructions can be accessed by a general-purpose or special-purpose computer. Combinations of the above should also be included within the scope of computer-readable media.

Upon reaching various computer system components, program code means in the form of computer-executable instructions or data structures can be transferred automatically from transmission media to computer storage media (or vice versa). For example, computer-executable instructions or data structures received over a network or data link can be buffered in RAM within a network interface module (e.g., a network interface card or “NIC”) and then eventually transferred to computer system RAM and/or to less volatile computer storage media at a computer system. Thus, it should be understood that computer storage media can be included in computer system components that also (or even primarily) utilize transmission media.

Computer-executable (or computer-interpretable) instructions comprise, for example, instructions that cause a general-purpose computer, special-purpose computer, or special-purpose processing device to perform a certain function or group of functions. The computer-executable instructions may be, for example, binaries, intermediate format instructions such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

Those skilled in the art will appreciate that the embodiments may be practiced in network computing environments with many types of computer system configurations, including personal computers, desktop computers, laptop computers, message processors, hand-held devices, multi-processor systems, microprocessor-based or programmable consumer electronics, network PCs, minicomputers, mainframe computers, mobile telephones, PDAs, pagers, routers, switches, and the like. The embodiments may also be practiced in distributed system environments where local and remote computer systems that are linked (either by hardwired data links, wireless data links, or by a combination of hardwired and wireless data links) through a network each perform tasks (e.g. cloud computing, cloud services and the like). In a distributed system environment, program modules may be located in both local and remote memory storage devices.

The present invention may be embodied in other specific forms without departing from its characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A semi-continuous quantum well micro light emitting diode (LED) array unit comprising:
a first block of LED pixels comprising a first LED pixel and a second LED pixel, wherein the first LED pixel and the second LED pixel share a first common active region, such that the first common active region is continuously shared by the first LED pixel and the second LED pixel; and
a second block of LED pixels comprising a third LED pixel and a fourth LED pixel, wherein the third LED pixel and the fourth LED pixel share a second common active region that is isolated from the first common active region, such that the second common active region is continuously shared by the third LED pixel and the fourth LED pixel,
wherein:
the first block of LED pixels is located proximately to the second block of LED pixels in the semi-continuous quantum well micro-LED array unit, and
as a result of the second common active region being isolated from the first common active region, the first block of LED pixels is discrete relative to the second block of LED pixels.

2. The semi-continuous quantum well micro-LED array unit of claim 1, wherein the first block of LED pixels includes a fifth LED that shares the first common active region.

3. The semi-continuous quantum well micro-LED array unit of claim 2, wherein the second block of LED pixels includes a sixth LED that shares the second common active region.

4. The semi-continuous quantum well micro-LED array unit of claim 1, wherein a number of LED pixels in the first block is different than a number of LED pixels in the second block.

5. The semi-continuous quantum well micro-LED array unit of claim 1, wherein the first block of LED pixels comprises a matrix of pixels having N×N dimensions.

6. The semi-continuous quantum well micro-LED array unit of claim 1, wherein the first block of LED pixels comprises a matrix of pixels having N×M dimensions.

7. The semi-continuous quantum well micro-LED array unit of claim 1, wherein the semi-continuous quantum well micro-LED array unit includes a third block of LED pixels, the third block of LED pixels having a third common active region that is shared among the LED pixels of the third block and that is isolated from the first common active region and the second common active region.

8. The semi-continuous quantum well micro-LED array unit of claim 1, wherein the second common active region being isolated from the first common active region operates to reduce crosstalk between the LED pixels of the second block and the LED pixels of the first block.

9. A semi-continuous quantum well micro light emitting diode (LED) array unit comprising:
a first block of LED pixels comprising a first LED pixel, a second LED pixel, and a third LED pixel, wherein the first LED pixel, the second LED pixel, and the third LED pixel share a first common active region, such that the first common active region is continuously shared by the first LED pixel, the second LED pixel, and the third LED pixel; and
a second block of LED pixels comprising a fourth LED pixel and a fifth LED pixel, wherein the fourth LED pixel and the fifth LED pixel share a second common active region that is isolated from the first common active region, such that the second common active region is continuously shared by the fourth LED pixel and the fifth LED pixel,
wherein:
the first block of LED pixels is located proximately to the second block of LED pixels in the semi-continuous quantum well micro-LED array unit, and
as a result of the second common active region being isolated from the first common active region, the first block of LED pixels is discrete relative to the second block of LED pixels.

10. The semi-continuous quantum well micro-LED array unit of claim 9, wherein a number of LED pixels in the first block of LED pixels is the same as a number of LED pixels in the second block of LED pixels.

11. The semi-continuous quantum well micro-LED array unit of claim 9, wherein a number of LED pixels in the first block of LED pixels is different than a number of LED pixels in the second block of LED pixels.

12. The semi-continuous quantum well micro-LED array unit of claim 9, wherein, prior to an etching process during which the semi-continuous quantum well micro-LED array unit was fabricated, the first common active region was coupled to the second common active region.

13. The semi-continuous quantum well micro-LED array unit of claim 9, a pixel pitch of the first pixel is less than or equal to 10 micrometers.

14. The semi-continuous quantum well micro-LED array unit of claim 9, wherein, as a result of (i) the first common active region being common between the LED pixels of the first block, (ii) the second common active region being common between the LED pixels of the second block, and (iii) the first common active region being isolated from the second common active region, a surface area to volume ratio of at least one of the first common active region or the second common active region is a reduced ratio due to a volume of the first or second common active region being increased.

15. The semi-continuous quantum well micro-LED array unit of claim 9, wherein a surface area to volume ratio of the first common active region is a reduced ratio due to a volume of the first common active region being increased.

16. The semi-continuous quantum well micro-LED array unit of claim 9, wherein a surface area to volume ratio of the first common active region is a reduced ratio due to a surface area of the first common active region being decreased.

17. A method for fabricating a semi-continuous quantum well micro light emitting diode (LED) array unit, said method comprising:
using a deep etching mask to discretely isolate a first quantum well of a first block of LED pixels from a second quantum well of a second block of LED pixels, wherein the first block of LED pixels includes a first LED pixel and a second LED pixel, wherein the second block of LED pixels includes a third LED pixel and a fourth LED pixel, and wherein, as a result of using the deep etching mask, the first block of LED pixels is discrete relative to the second block of LED pixels;
using a shallow etching mask to partially isolate the first LED pixel from the second LED pixel within the first block of LED pixels, wherein partially isolating the first LED pixel from the second LED pixel involves etching a first portion of the first block of LED pixels to a first depth that causes the first quantum well to continuously span both the first LED pixel and the second LED pixel such that the first quantum well is a first shared quantum well that is shared between the first LED pixel and the second LED pixel; and
using the shallow etching mask to partially isolate the third LED pixel from the fourth LED pixel within the second block of LED pixels, wherein partially isolating the third LED pixel from the fourth LED pixel involves etching a second portion of the second block to a second depth that causes the second quantum well to continuously span both the third LED pixel and the fourth LED pixel such that the second quantum well is a second shared quantum well that is shared between the third LED pixel and the fourth LED pixel.

18. The method of claim 17, wherein the first depth is the same as the second depth.

19. The method of claim 17, wherein the shallow etching mask is used subsequent in time to the deep etching mask.

20. The method of claim 17, wherein the shallow etching mask is concurrently used to etch both the first block of LED pixels and the second block of LED pixels.
